(19) United States
(12) Patent Application Publication
(10) Pub. No.: US 2016/0087343 A1
(43) Pub. Date: Mar. 24, 2016

(54) ANTENNA WITH PROXIMITY SENSOR FUNCTION

(71) Applicant: Acer Incorporated, New Taipei City (TW)

(72) Inventors: Kun-Sheng CHANG, New Taipei City (TW); Ching-Chi LIN, New Taipei City (TW)

(21) Appl. No.: 14/591,996

(22) Filed: Jan. 8, 2015

(30) Foreign Application Priority Data
Sep. 22, 2014 (TW) 103132633

(51) Int. Cl. H01Q 19/00; G01V 3/02; G01R 29/24; H01Q 1/50

(52) U.S. Cl. CPC H01Q 19/005; H01Q 1/50; G01V 3/02; G01R 29/24

(57) ABSTRACT

An electronic device having a radiation element having a feed point, a parasitic element having a ground point, an extension portion extending from one end of the parasitic element, and a proximity sensing unit in communication with the extension portion. A reactive element, e.g., a radio frequency choke, is connected between the proximity sensing unit and the extension portion and enables the proximity sensing unit to employ at least the parasitic element and the extension portion as sensing pads to sense the proximity of an object to the electronic device.

This application claims priority under 35 U.S.C. §119 to Taiwan patent application TW 103132633, filed on Sep. 22, 2014, the disclosure of which is incorporated herein by reference in its entirety.

### TECHNICAL FIELD

Embodiments of the present invention are directed antennas for electronic devices.

### BACKGROUND

In recent years, consumer electronic devices, particularly wireless electronic devices, have seen explosive growth in the marketplace due to, among other things, user convenience. Such wireless devices must, however, comply with relevant regulations. Regulatory bodies such as the U.S. Federal Communications Commission (FCC) and Conformite Europeene (CE) have developed a variety of wireless communication criterions and regulations. For example, electronic device and associated antenna designs must comply with regulations known as Specific Absorption Rate or SAR. These regulations govern how much radiation may be transmitted by a given device to ensure the safety and well being a user.

In some newer wireless electronic devices, a detection sensor is provided for detecting a distance between the antenna of the electronic device and a user's body. If the sensor detects that the distance between the antenna and user's body is closer than a default or predetermined distance, then the electronic device will cause the power being transmitted via the antenna to be reduced so as to ensure compliance with the relevant SAR regulations. Unfortunately, however, such a sensor, typically in the form of a sensor pad for detecting changes in capacitance, is larger than is often desired and can detrimentally impact overall antenna performance and take up critical “real estate.”

Further, in addition to the sensor pad itself, additional components such as an inductor and capacitor are sometimes needed to implement such a sensor to achieve a desired level of performance. However, such additional components add to the cost of the overall design.

Embodiments of the present invention aim to provide an electronic device including an integrated proximity detection function and tunable antenna.

### SUMMARY

The electronic device described herein includes a radiation element, a first reactance element, a parasitic element, a second reactance element, an extension portion, a third reactance element, and a proximity sensing unit.

The radiation element includes a feed branch and an open-end branch. The first reactance element is connected to the radiation element between the feed branch and a feed point. The parasitic element includes a ground branch and open-end branch. The ground branch is connected to a system ground and at last part of the open-end branch is parallel to, and opposite, the open-end branch of the radiation element. The second reactance element is disposed in the ground branch of the parasitic element adjacent the system ground.

The extension portion is connected to the parasitic element and to the proximity sensing unit. The third reactance element is provided on the extension portion near the proximity sensing unit. When the radiation element and the parasitic element form an antenna to transmit and receive multi band signals, the proximity sensing unit can nevertheless simultaneously detect an approaching object using the extension portion and the parasitic element.

In sum, the present invention provides an electronic device that includes an antenna with an integrated proximity sensor, such that the antenna and proximity sensor can operate independently of one another and not cause interference to with one another, all while reducing the layout area used compared to prior art antenna and proximity sensor implementations.

### BRIEF DESCRIPTION OF THE DRAWINGS

Embodiments are described herein in conjunction with the accompanying drawings, in which:

FIG. 1 is a schematic diagram illustrating an electronic device according to an embodiment of the present invention;

FIG. 2 is a schematic diagram illustrating an electronic device according to another embodiment of the present invention;

FIG. 3 is a block diagram of one possible implementation of an impedance matching unit according to an embodiment of the present invention; and

FIG. 4 is a graph illustrating passive performance of an antenna according to an antenna formed by a radiation element and a parasitic element according to an embodiment of the present invention.

### DESCRIPTION OF EXAMPLE EMBODIMENTS

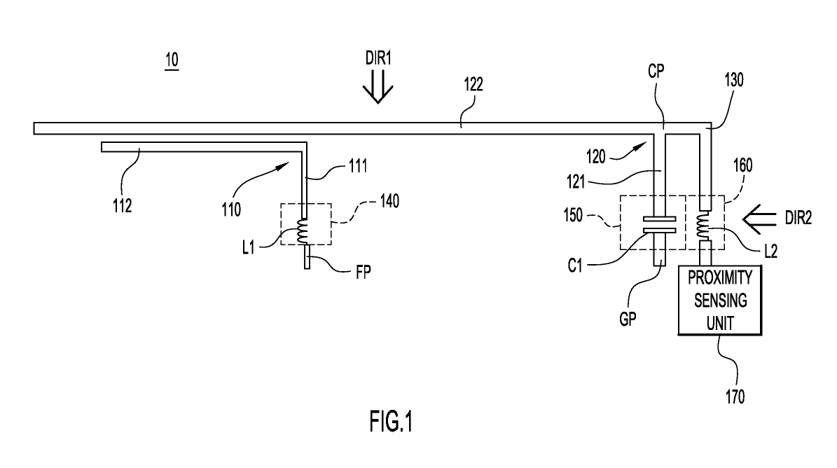

FIG. 1 is a schematic diagram illustrating an electronic device according to an embodiment of the present invention. As shown, electronic device 10 includes a radiation element 110, a parasitic element 120, an extension portion 130, a first reactance element 140, a second reactance element 150, a third reactance element 160 and a proximity sensing unit 170. Radiation element 110 includes a feed branch 111 and an open branch 112. First reactance element 140 is connected to the feed branch 111 on one end thereof and to a Feed Point (FP) on another end thereof.

Parasitic element 120 includes a ground branch 121 and an open branch 122. A Ground Point (GP) of ground branch 121 of parasitic element 120 is connected to a system ground plane and at least part of open branch 122 of parasitic element 120 is opposite, and parallel, to open branch 112 of radiation element 110.

The second reactance element 150 is provided on ground branch 121 of parasitic element 120 and is adjacent to the GP of ground branch 121.

Extension portion 130 is connected to parasitic element 120 and is adjacent to proximity sensing unit 170. For example, in the depicted embodiment, extension portion 130 extends from a connection point (CP) of ground branch 121 and open branch 122 of parasitic element 120.

The third reactance element 160 is provided on the extension portion 130, and is adjacent the proximity sensing unit 170.

Radiation element 110 and parasitic element 120 are configured to act as an antenna and receive and transmit at a plurality of radio frequency (RF) signals via feed point FP.

Proximity sensing unit 170 is configured to detect an approaching object (e.g., human tissue) through extension portion 130 and open portion 122 of parasitic element 120. In one embodiment, proximity sensing unit 170 senses a capacitance value associated with extension portion 130 and/or open branch 122 of parasitic element 120 as open branch 122 or extension portion 130 approaches an object. Based on the detected capacitance value, proximity sensing unit 170 determines whether an object is close to open branch 122 or extension portion 130, i.e., whether the object is approached from direction DIR1 or direction DIR2.

One application for the present invention is mobile telephony. In such an application, a center frequency of a high-frequency band may be located at, e.g., 800 MHz or more. For such a high frequency band, the first reactance element 140 and the second reactance element 150 are selected such that they are conductive. On the other hand, first reactance element 140 and the second reactance element 150 are selected such that, at a base band frequency, e.g., 0-1 MHz, those reactive elements are effectively open circuits.

Third reactance 160, on the other hand, is selected such that it effectively creates an open circuit at the high-frequency bands, but acts as a short circuit at the base band frequency. Thus, when high-frequency RF signals are flowing via radiation element 110 and parasitic element 120, the third reactance element 160 acts an RF choke, so that the performance of radiation element 110 and parasitic element 120 is not detrimentally impacted by proximity sensing unit 170.

In a similar fashion, proximity sensing unit 170 is not detrimentally impacted by RF signals and related elements. More specifically, proximity sensing unit 170 operates at base band frequencies and, at such frequencies, the first reactance element 140 and the second reactance element 150 act as open circuits. As a result, current associated with an accumulation of charge built up on open branch 122 or extension portion 130 flows directly to proximity sensing unit 170, which can then perform accurate distance detection as the relevant (base band) current is concentrated to flow back to proximity sensing unit 170.

Likewise, since third reactance element 160 acts as an RF choke, the antenna, formed by radiation element 110 and parasitic element 120, and the proximity sensing unit 170 can operate at the same time but do not interfere each other.

In the present embodiment, the first reactance element 140 includes an inductor L1, the second reactance element 150 includes a capacitor C1 and the third reactance element 160 includes an inductor L2.

The capacitance value and the inductance value of each of the reactance elements can be selected based on circuit configuration and the actual high frequencies and base band frequencies selected.

As shown in FIG. 1, the first reactance element 140, L1, is connected between the feed point GP and feed branch 111 of radiation element 110 and is intended to pass high frequencies. As such, the value of the inductance of L1 is preferably smaller than the value of inductance of inductor L2 of the third reactance element 160, which is configured to act as an RF choke. As a practical example, the inductance value of inductor L1 can be set to be less than 10 nH, and the inductance value of inductor L2 can be set to approximately 100 nH.

The second reactance element, capacitor C1, 150 can be set to a relatively large capacitance in order to block ground current. As a practical example, the capacitance value of capacitor C1 may be on the order of 15 pF. Those skilled in the art will appreciate that other electrical components may be employed to achieve the same current blocking effect, and the present invention should not be construed as being limited to the foregoing practical example.

In the present embodiment, the RF signals may include a first RF signal and a second RF signal, at least. The length of radiation element 110 may be set close to a quarter of a wavelength of the first radio frequency signal, whereas the length of parasitic element 120 may be set close to a quarter wavelength of the second radio frequency signal.

It is noted that since first reactance element 140, i.e., inductor L1, is connected between feed point FP and radiation element 110, the length of radiation element 110 can be shortened due to the reactive effect of the inductor. In other words, the length of radiation element 110 may be set equal to or shorter than a quarter wavelength of the first RF signal.

The length of parasitic element 120 can also be adjusted as a result of associated circuit elements.

Radiating element 110 can be configured to operate as a monopole antenna. That is, an RF signal can be fed through feed point FP towards radiation element 110 for transmission over the air, or an RF signal received over the air by radiation element 110 can be fed to receive circuitry (not shown) via feed point FP. Radiation element 110 and parasitic element 120 may further be configured to be resonant at the wavelength of the second RF signal.

With the described configuration, the antenna of electronic device 10 can be configured to transmit/receive the first RF signal and second RF signal and adjacent frequency bands of the first RF signal and second RF signal.

In one possible implementation, the center frequency of the first RF signal and the center frequency of the second RF signal may be, e.g., 1.88 GHz and 900 MHz, respectively (which correspond to 3G and LTE frequency bands), but the present invention should not be construed as being so limited.

In the embodiment depicted in FIG. 1, radiation element 110 and parasitic element 120 are L-shaped. The open angle between feed branch 111 and open branch 112 of radiation element 110 may be 90 degrees. Likewise, the angle between ground branch 121 and open branch 122 of parasitic element 120 may be 90 degrees. However, those skilled in the art will appreciate that the invention should not be construed as being so limited.

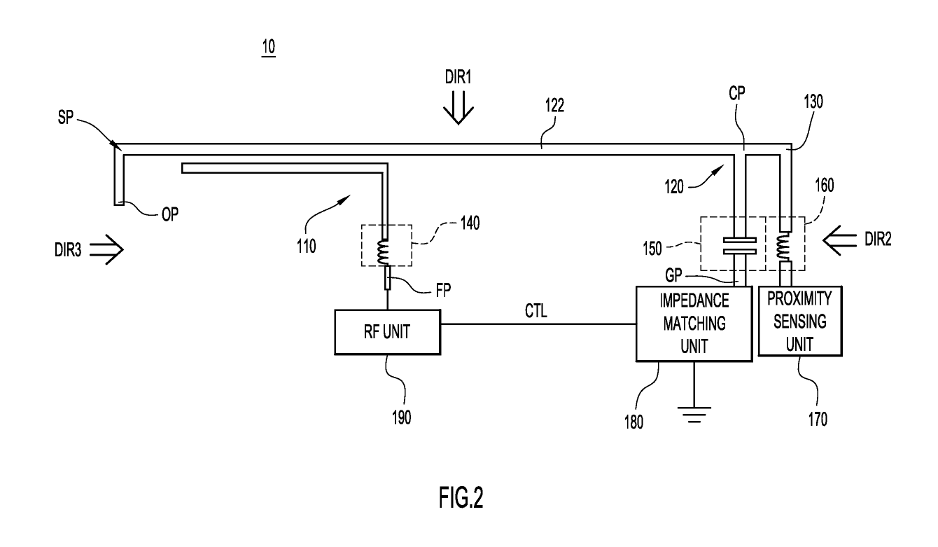

FIG. 2. is a schematic diagram illustrating an electronic device according to another embodiment of the present invention. As is depicted in FIG. 2, compared to the embodiment shown in FIG. 1, open branch 122 of parasitic element 120 includes another bending portion designated as OP.

Also in FIG. 2, electronic device 10 comprises an impedance matching unit 180 which is connected to parasitic element 120 via ground point GP and is further in communication with feed point FP via a control signal CTL from RF unit 190. The other components shown in FIG. 2 are identical to those shown in FIG. 1 and are, therefore, not described again.

With continued reference to FIG. 2, because of the additional bending portion OP, proximity sensing unit 170 can detect an approaching object not only from direction DIR1 and DIR2, but can now also more accurately detect an approaching object from direction DIR3.

In a typical implementation, parasitic element 120 is disposed proximate one side of electronic device 10, for example on the top-edge of the electronic device. By virtue of the extension portion 130 and bending portion OP, proximity sensing unit 170 has the ability to detect an approaching object at the top edge of the electronic device (i.e., from the direction DIR1,) a right side edge of the electronic device (i.e., from the direction DIR2, corresponding to extension portion 130 which is perpendicular to the section of open branch 122 of parasitic element 120), and the left side edge of the electronic device (i.e., from direction DIR3, corresponding to bending portion OP).

In addition, bending portion OP may also enable an overall antenna size to be reduced, where the antenna comprises radiating element 110 and parasitic element 120.

RF unit 190 is configured to operate in conjunction with impedance matching unit 180. While receiving/transmitting an RF signal, RF unit 190 is configured, according to the center frequency of the received/transmitted RF signal, to send a control signal to impedance matching unit 180 to adjust the antenna impedance value so that overall performance of the antenna is increased. Impedance matching unit 180 may include a load, a plurality of reactive elements and associated switches.

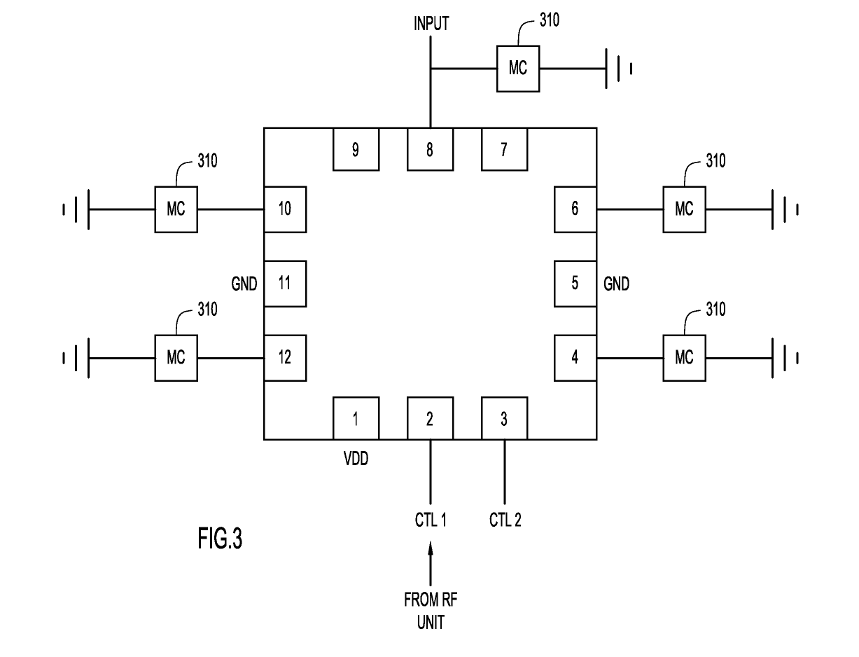

An example impedance matching unit 180 is shown in FIG. 3. Impedance matching unit 180 may be implemented as a separate chip with multiple switches. In the depicted embodiment, a control word comprising 2 bits CTL1, CTL2 transmitted from RF unit 190 enables impedance matching unit 180 to introduce a selected one or more of reactance elements, e.g., inductors or capacitors, to modify the impedance of the antenna. As shown, each reactance element 310 may be connected to ground. With a two bit control word, up to four different reactive elements may be independently switched into or out of the antenna circuit.

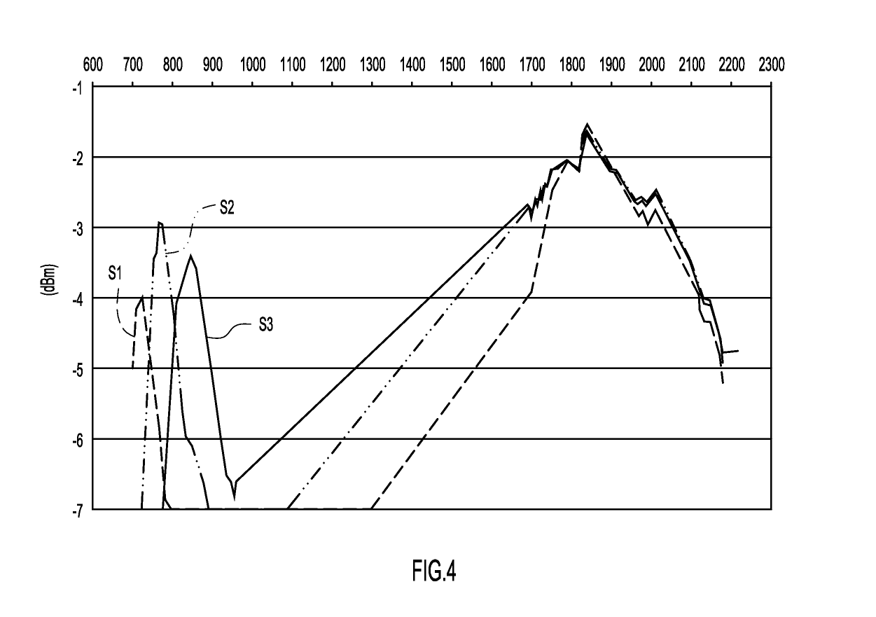

FIG. 4 is a graph illustrating passive performance of an antenna formed by radiation element 110 and a parasitic element 120.

For the plotted graph, the length of radiation element 110 is set smaller than a quarter of the wavelength of an RF signal at 1.88 GHz, and the length of the parasitic element 120 is set smaller than a quarter of the wavelength of an RF signal at 900 MHz. A length of open portion 122 of parasitic element was about 16 mm. The portion of extension portion 130 that is perpendicular to open branch 122 was about 8 mm. Bending portion OP was about 2 mm.

Referring to FIG. 4, curves S1-S3 in the figure correspond to different impedances supplied by impedance matching unit 180. By switching among the three settings, the efficiency of the antenna in the 700-950 MHz band, and in the 1700-2200 MHz band achieves improved performance, even in the presence of proximity sensing unit 170. That is, the antenna can effectively cover the bands corresponding to of 3G (third generation, 3G) and Long Term Evolution (LTE).

Those skilled in the art will appreciate that the foregoing arrangement is quite different from, e.g., a conventional approach that includes 10 mm×10 mm proximity sensing pads that might be arranged on either side of the antenna.

In sum, the present invention provides an electronic apparatus comprising a fully integrated tunable antenna and proximity sensor. By selectively incorporating reactance elements, the tunable antenna and proximity sensor can operate simultaneously without interfering with each other. Moreover, with the embodiment described herein, a significant amount of layout area not consumed.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

What is claimed is:

1. An electronic device, comprising:
a radiation element having a feed point;
a parasitic element having a ground point;
an extension portion extending from one end of the parasitic element; and
a proximity sensing unit in communication with the extension portion, and configured to employ at least one of a portion of the parasitic element and the extension portion as a capacitive element to detect an accumulation of charge thereon.

2. The electronic device of claim 1, further comprising:
a first reactance element connected between the feed point and the radiation element;
a second reactance element connected between the ground point and the parasitic element; and
a third reactance element connected between the extension portion and the proximity sensing unit.

3. The electronic device of claim 1, wherein the proximity sensing unit is configured to detect whether an object is close to the electronic device.

4. The electronic device of claim 1, wherein at least a portion of the extending portion is arranged substantially perpendicular to a portion of the parasitic element.

5. The electronic device of claim 1, wherein the radiation element is L-shaped.

6. The electronic device of claim 5, wherein the parasitic element is L-shaped.

7. The electronic device of claim 6, wherein at least a portion of the parasitic element is parallel to, and opposite, at least a portion of the radiation element.

8. The electronic device of claim 1, wherein the first reactance element comprises a first inductor, the second reactance element comprises a capacitor and the third reactance element comprises a second inductor.

9. The electronic device of claim 8, wherein the first inductor has a lower value of inductance compared to a value of inductance of the second inductor.

10. The electronic device of claim 8, wherein the third reactance element operates as a radio frequency (RF) choke with respect to RF signals transmitted or received by an antenna comprising the radiation element and the parasitic element.

11. The electronic device of claim 1, further comprising a radio frequency (RF) unit in communication with the feed point, and an impedance matching unit in communication with the ground point, wherein the RF unit supplies a control signal to the impedance matching unit resulting in a change of impedance for an antenna comprising the radiation element and the parasitic element.

12. The electronic device of claim 1, further comprising a bending portion that extends from the parasitic element at an opposite end from which the extension portion extends.

13. An electronic device, comprising:
a radiation element comprising a feed branch and an open branch;
a first reactance element connected to a feed point of the feed branch;
a parasitic element comprising a ground branch and an open branch, the ground branch being in communication with a system ground plane at a ground point of the ground branch, and at least a portion of the open branch of the parasitic element being parallel to the open branch of the radiation element;
a second reactance element connected to the ground branch of the parasitic element adjacent to the ground point;
an extension portion connected to a connection point of the open branch and the ground branch of the parasitic element;
a proximity sensing unit in communication with to the extension portion; and
a third reactance element disposed between the extension portion and the proximity sensing unit,
wherein the radiation element and the parasitic element form an antenna for receiving a plurality of RF signals, and
the proximity sensing unit is configured to detect an approaching object to the electronic device via monitoring accumulated charge on the extension portion and the open portion of parasitic element.

14. The electronic device of claim 13, further comprising:
an impedance matching unit connected between the ground branch of the parasitic element and the system ground.

15. The electronic device of claim 14, further comprising:
a radio frequency (RF) unit connected to a feed point of the feed branch and to the impedance matching unit,
wherein the RF unit is configured to, based on a received radio frequency signal, transmit a control signal to the impedance matching unit to adjust an impedance value of the impedance matching unit.

16. The electronic device of claim 14, wherein the impedance matching unit comprises:
a plurality of separately selectable reactance elements connectable between the system ground and the parasitic element.

17. The electronic device of claim 13, wherein the proximity sensing unit is configured to detect an approaching object to the electronic device while the antenna simultaneously transmits the RF signals.

18. The electronic device of claim 13, wherein a center frequency of the RF signals is in a high frequency band, and the first reactance element and the second reactance element operate to allow the RF signals to pass but operate as open circuits to base band frequencies, and
wherein the third reactance element operates as an open circuit to the RF signals but operates to allow base band frequencies to pass.

19. The electronic device of claim 18, wherein the first reactance element is a first inductor, the second reactance element is a capacitor, and the third reactance element is a second inductor, wherein the second inductor has an inductance value that is greater than an inductance value of the first inductor.

20. The electronic device of claim 13, wherein the RF signals comprise first RF signals and second RF signals, the radiation element is configured to have a length that is less than or equal to a quarter of a wavelength of the first RF signals, and the parasitic element is configured to have a length that is less than or equal to a quarter wavelength of the second RF signals.
